(19) United States
(12) Patent Application Publication
(10) Pub. No.: US 2026/0245836 A1
(43) Pub. Date: Aug. 20, 2026

(54) SPUTTERING APPARATUS AND METHOD OF MANUFACTURING SEMICONDUCTOR DEVICE

(71) Applicant: Mitsubishi Electric Corporation, Tokyo (JP)

(72) Inventor: Satoshi YASUI, Tokyo (JP)

(73) Assignee: Mitsubishi Electric Corporation, Tokyo (JP)

(21) Appl. No.: 19/395,942

(22) Filed: Nov. 20, 2025

(30) Foreign Application Priority Data
Feb. 20, 2025 (JP) 2025-025741

(51) Int. Cl. H01J 37/32; C23C 14/34; C23C 14/48; C23C 14/50

(52) U.S. Cl. CPC H01J 37/32559; C23C 14/34; C23C 14/48; C23C 14/50; H01J 37/32568; H01J 37/32715; H01J 2237/332; H10P 14/45; H10P 30/20

(57) ABSTRACT

An object of the present disclosure is to provide sputtering apparatus capable of preventing adhesion of sputter particles to an unnecessary area and ensuring in-plane uniformity of a film thickness distribution in a whole substrate after sputtering and a method of manufacturing a semiconductor device using the sputtering apparatus. A sputtering apparatus according to the present disclosure includes: a vacuum chamber; a stage to which a substrate is mounted in the vacuum chamber; and an adhesion preventive unit disposed to be separated from the substrate between a sputter target provided in the vacuum chamber and an end portion of the substrate, wherein the adhesion preventive unit includes an adhesion preventive unit electrode disposed via an insulating part, the stage includes a stage electrode disposed in an end portion, and a power source is disposed between the adhesion preventive unit electrode and the stage electrode.

### BACKGROUND

### Technical Field

The present disclosure relates to a sputtering apparatus and a method of manufacturing a semiconductor device using the sputtering apparatus.

### Description of the Background Art

In a field of a power device semiconductor, sputtering is performed on a relative thin substrate (also referred to as “a wafer”) using a target larger than an outer diameter of the substrate to form a metal film. In sputtering, there is a problem that sputter particles flying from an end portion of a target approach in an oblique direction with respect to the substrate and adhere to an unnecessary area. Herein, the unnecessary area indicates an area such as an edge portion of the substrate and a side surface of a stage to which the sputter particles basically need not to adhere.

As a measure against the above problem, conventionally disclosed is a technique of locating an adhesion preventive unit in an end portion of the substrate and preventing adhesion of the sputtering particles to an edge portion of the substrate (for example, refer to Japanese Patent Application Laid-Open No. 2003-183810).

### SUMMARY

In Japanese Patent Application Laid-Open No. 2003-183810, the substrate after sputtering includes a region in which a film is not formed or a region with a small film thickness even when a film is formed. Thus, in-plane uniformity of a film thickness distribution cannot be ensured in the whole substrate after sputtering. Accordingly, there is a problem that a valid area for manufacturing a product is reduced and production efficiency is deteriorated.

An object of the present disclosure is to provide a sputtering apparatus capable of preventing adhesion of sputter particles to an unnecessary area and ensuring in-plane uniformity of a film thickness distribution in the whole substrate after sputtering and a method of manufacturing a semiconductor device using the sputtering apparatus.

A sputtering apparatus according to the present disclosure includes: a vacuum chamber; a stage to which a substrate is mounted in the vacuum chamber; and an adhesion preventive unit disposed to be separated from the substrate between a sputter target provided in the vacuum chamber and an end portion of the substrate, wherein the adhesion preventive unit includes an adhesion preventive unit electrode disposed via an insulating part, the stage includes a stage electrode disposed in an end portion, and a power source is disposed between the adhesion preventive unit electrode and the stage electrode.

According to the present disclosure, prevented is adhesion of sputter particles to an unnecessary area, and in-plane uniformity of a film thickness distribution in the whole substrate after sputtering can be ensured.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating a configuration of a sputtering apparatus according to an embodiment 1.

FIG. 2 is a diagram illustrating sputtering according to the embodiment 1.

FIG. 3 is a diagram illustrating sputtering according to the embodiment 1.

FIG. 4 is a diagram for explaining motion energy of sputter particles.

FIG. 5 is a diagram illustrating a configuration of a sputtering apparatus according to a modification example 1 of the embodiment 1.

FIG. 6 is a diagram illustrating a configuration of a sputtering apparatus according to a modification example 2 of the embodiment 1.

FIG. 7 is a flow chart illustrating a method of manufacturing a semiconductor device according to an embodiment 2.

### DESCRIPTION OF THE PREFERRED EMBODIMENTS

### Embodiment 1

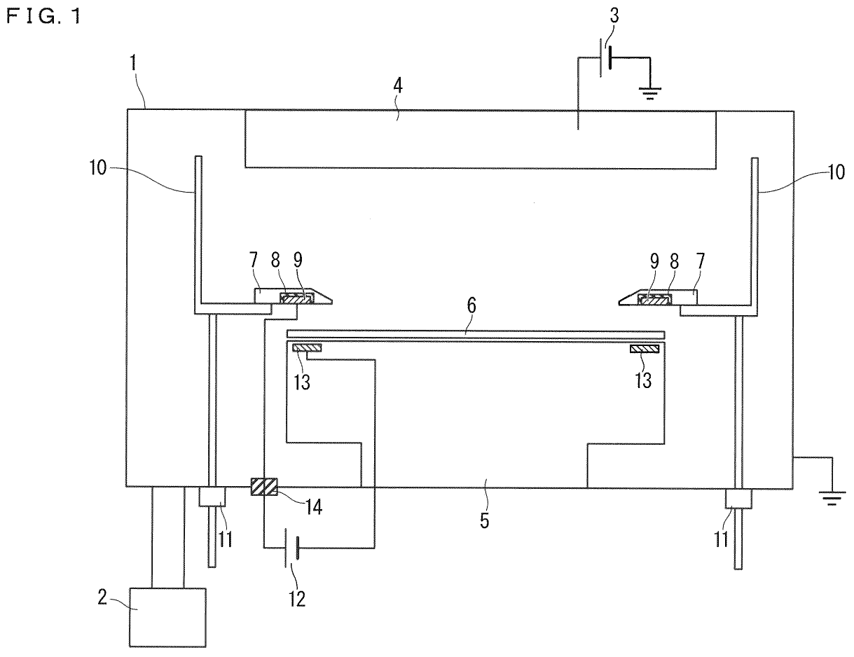

FIG. 1 is a diagram illustrating a configuration of a sputtering apparatus according to an embodiment 1.

The sputtering apparatus includes a vacuum chamber 1 and a vacuum pump 2, and the vacuum chamber 1 is evacuated using the vacuum pump 2 in sputtering.

An electrostatic chuck stage 5 is provided in the vacuum chamber 1, and a substrate 6 is disposed on the electrostatic chuck stage 5 in the sputtering. The electrostatic chuck stage 5 includes a stage electrode 13 on an end portion. The stage electrode 13 has a circular shape in a plan view.

A sputter target 4 is provided in a position facing the substrate 6 in the sputtering. A discharge power source 3 is connected to the sputter target 4, and when the discharge power source 3 enters an ON state, electrical discharge occurs in the vacuum chamber 1, and the sputtering can be started.

In the sputtering, an adhesion preventive unit 7 is disposed between the sputter target 4 and an end portion of the substrate 6. The adhesion preventive unit 7 has a circular shape along the end portion of the substrate 6, and is disposed away from the substrate 6. The adhesion preventive unit 7 includes an adhesion preventive unit electrode 9 with a surface on a side of the substrate 6 exposed. The adhesion preventive unit electrode 9 is covered by an insulating part 8 in the adhesion preventive unit 7.

A holding unit 10 holds the adhesion preventive unit 7. An adhesion preventive unit elevating mechanism 11 can move the holding unit 10 in an up-down direction, and can also move the adhesion preventive unit 7 in the up-down direction by moving up and down the holding unit 10. When the substrate 6 is disposed on or detached from the electrostatic chuck stage 5, the holding unit 10 is moved using the adhesion preventive unit elevating mechanism 11 to increase a space between the electrostatic chuck stage 5 and the adhesion preventive unit 7. Although FIG. 1 exemplifies a case where the holding unit 10 (the adhesion preventive unit 7) is moved up and down, the electrostatic chuck stage 5 may be moved up and down. In this case, a mechanism of moving the electrostatic chuck stage 5 up and down is necessary.

An adhesion preventive unit power source 12 is disposed between the adhesion preventive unit electrode 9 and the stage electrode 13. In the sputtering, when the adhesion preventive unit power source 12 enter the ON state, electrical field occurs between the adhesion preventive unit electrode 9 and the stage electrode 13. The insulating part 14 is provided to insulate a wiring between the adhesion preventive unit electrode 9 and the stage electrode 13 from the vacuum chamber 1.

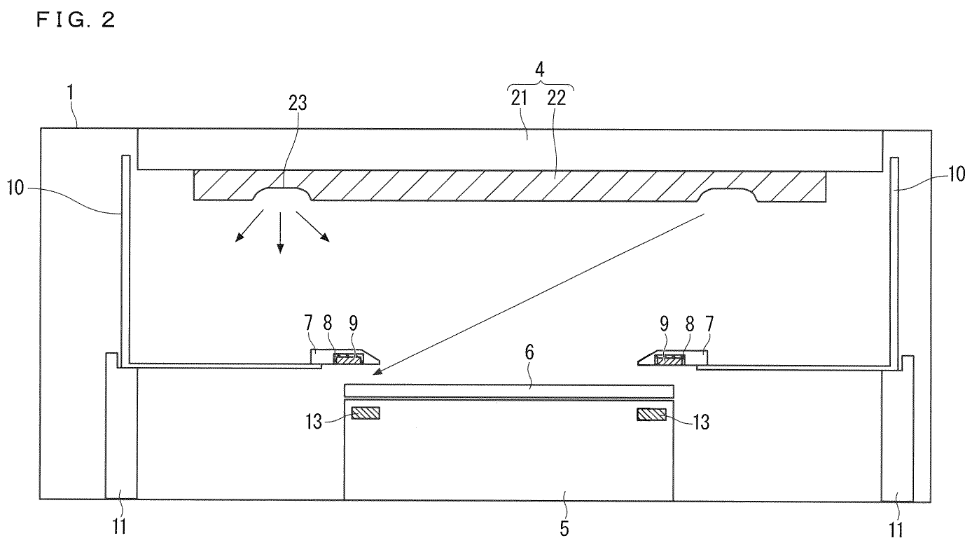

FIG. 2 is a diagram illustrating sputtering according to the embodiment 1, and illustrates a part of FIG. 1.

The sputter target 4 is made up of a backing plate 21 and a target material 22. The backing plate 21 is a base of the target material 22.

When argon gas is introduced into the vacuum chamber 1 and the discharge power source 3 enters the ON state after the vacuum chamber 1 is vacuumed using the vacuum pump 2, electrical discharge occurs in the vacuum chamber 1. Then, when ionized argon ions collide with an erosion 23 of the target material 22, sputter particles (particles of a material constituting the target material 22) fly in all directions from the target material 22 and adhere to the substrate 6.

The erosion 23 corresponds to a region having higher magnetic field intensity during discharge than the other region in the target material 22. When the magnetic field intensity in the erosion 23 is large, a density of argon ions gets high. Thus, a larger amount of argon ions collide with the erosion 23 than the other region. As a result, a larger amount of sputter particles fly in all directions from the erosion 23 than the other region (arrows in FIG. 2). As illustrated in FIG. 2, the erosion 23 is gradually concaved as argon ions collide with the erosion 23. The erosion 23 has a circular shape in a plan view.

The adhesion preventive unit 7 can prevent adhesion of sputter particles flying from the erosion 23 close to the adhesion preventive unit 7 to an unnecessary area. However, there is a possibility that sputter particles flying from the erosion 23 away from the adhesion preventive unit 7 approach at a small angle with respect to the substrate, pass between the adhesion preventive unit 7 and the substrate 6, and intrude and adhere to the unnecessary area. The sputtering apparatus according to the present embodiment 1 prevents the sputter particles from approaching at a small angle with respect to the substrate, passing between the adhesion preventive unit 7 and the substrate 6, and adhering to the unnecessary area.

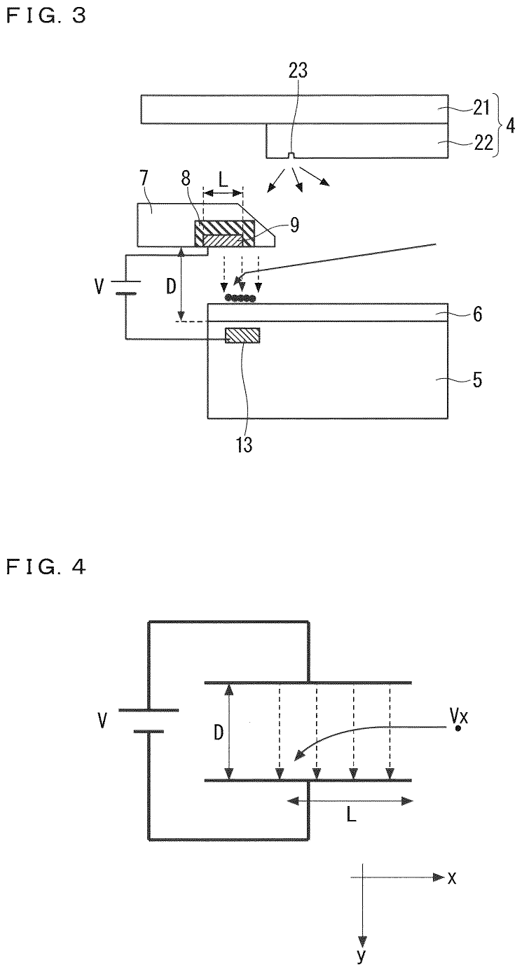

FIG. 3 is a diagram illustrating sputtering according to the embodiment 1, and illustrates a part of FIG. 2.

The sputtering apparatus according to the present embodiment 1 applies voltage between the adhesion preventive unit electrode 9 and the stage electrode 13. “V” in the diagrams corresponds to the adhesion preventive unit power source 12 illustrated in FIG. 1.

When the adhesion preventive unit power source 12 enters the ON state and voltage is applied between the adhesion preventive unit electrode 9 and the stage electrode 13, electrical field occurs between the adhesion preventive unit electrode 9 and the stage electrode 13. The sputter particles approaching at the small angle with respect to the substrate 6 change trajectories under influence of the electrical field between the adhesion preventive unit electrode 9 and the stage electrode 13, and adhere to the substrate 6. Accordingly, adhesion of the sputter particles to the unnecessary area can be prevented.

FIG. 4 is a diagram for explaining motion energy of the sputter particles.

The motion energy of the sputter particles flying between the adhesion preventive unit electrode 9 and the stage electrode 13 is modeled on a parallel plate capacitor illustrated in FIG. 4.

One of two electrodes constituting the parallel plate capacitor illustrated in FIG. 4 corresponds to the adhesion preventive unit electrode 9, and the other one thereof corresponds to the stage electrode 13. “V”, “D”, and “L” in FIG. 4 correspond to “V”, “D”, and “L” in FIG. 3, respectively. That is to say, “V” indicates voltage applied between the adhesion preventive unit electrode 9 and the stage electrode 13 by the adhesion preventive unit power source 12, “D” indicates a distance from the adhesion preventive unit 7 to an end portion of the electrostatic chuck stage 5, and “L” indicates a width of the adhesion preventive unit electrode 9.

In FIG. 4, it is assumed that sputter particles having a speed Vₓ approaches a center of a parallel plate capacitor, to which voltage V [V] is applied, horizontally with respect to the electrode. At this time, a motion equation of the sputter particles in the capacitor in a y direction is expressed by the following expression (1). In the expression (1), “e” indicates a charge elementary quantum, and “m” indicates a mass of the sputter particles.

$$\begin{matrix}[ Expression 1 ] & \\ \frac{{d}^{2} y}{{dt}^{2}} = \frac{eV}{mD} & ( 1 )\end{matrix}$$

When a time at which the sputter particles approach an end portion of the capacitor is “t=0” and a position in the y direction is “y=0”, a relationship between the applied voltage V and the speed Vₓ of the sputter particles using a distance L the sputter particles fly in the capacitor is expressed by the following expression (2).

$$\begin{matrix}[ Expression 2 ] & \\ V = \frac{m}{e} {( \frac{{V}_{x} D}{L} )}^{2} … & ( 2 )\end{matrix}$$

When the expression (2) is summed up in the motion energy of the sputter particles and is expressed in a representative range of motion energy of the sputter particles, the following expression (3) is established. A unit in the expression (3) is electron volt. For example, “the journal of the Minerals, 2011, Vol. 63, No. 6, P. 48” discloses the representative range of motion energy of the sputter particles.

$$\begin{matrix}[ Expression 3 ] & \\ 0 < \frac{1}{2} {mV}_{x}^{2} = \frac{V}{2} {( \frac{L}{D} )}^{2} \leq 30 & ( 3 )\end{matrix}$$

When the expression (3) is summed up, 0<VL²/D²≤60 is established. The voltage V satisfying 0<VL²/D²≤60 needs to be applied to change a trajectory of the sputter particles having the motion energy in the range described above.

As described above, the sputtering apparatus according to the present embodiment 1 applies the voltage between the adhesion preventive unit electrode 9 and the stage electrode 13 in the sputtering. Accordingly, the trajectories of the sputter particles approaching between the adhesion preventive unit 7 and the substrate 6 at a small angle with respect to the substrate 6 are bended in a vertical direction with respect to the substrate 6 by action of electrostatic force, and the sputter particles adhere to the end portion of the substrate 6. Accordingly, intrusion and adhesion of the sputter particles to the unnecessary area can be prevented. That is to say, prevented is adhesion of the sputter particles to the unnecessary area, and in-plane uniformity of the film thickness distribution in the whole substrate 6 after sputtering can be ensured.

In the sputtering apparatus according to the present embodiment 1, the adhesion preventive unit 7 and the substrate 6 do not have contact with each other in the sputtering. Accordingly, damage on the substrate 6 can be prevented.

### Modification Example 1

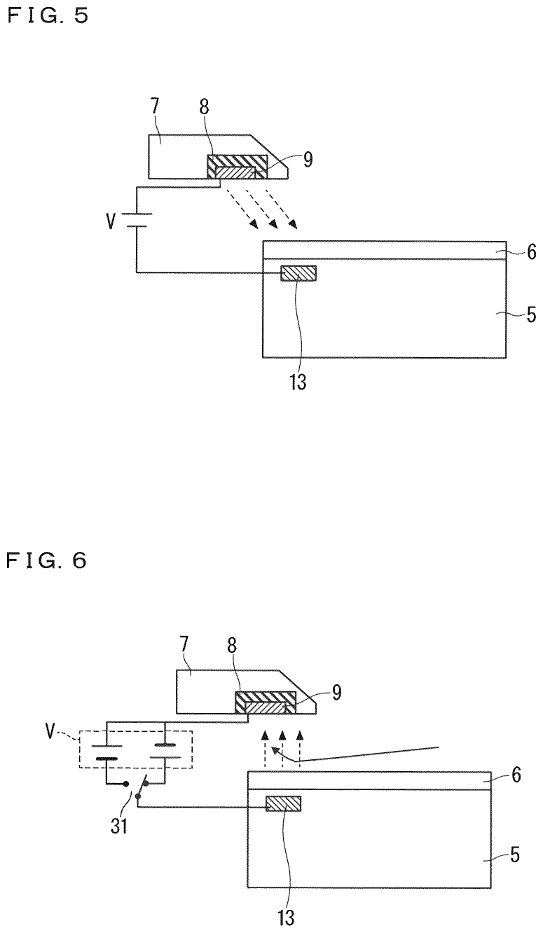

FIG. 5 is a diagram illustrating a configuration of a sputtering apparatus according to a modification example 1 of the embodiment 1. “V” in the diagrams corresponds to the adhesion preventive unit power source 12 illustrated in FIG. 1.

In the sputtering apparatus according to the modification example 1, the adhesion preventive unit electrode 9 is disposed on an outer side than the stage electrode 13.

According to the modification example 1, a direction of electrical field between the adhesion preventive unit electrode 9 and the stage electrode 13 is directed inward from outside of the substrate 6. Thus, a speed of the sputter particles is reduced and intrusion thereof to the unnecessary area can be efficiently prevented.

### Modification Example 2

FIG. 6 is a diagram illustrating a configuration of a sputtering apparatus according to a modification example 2 of the embodiment 1. “V” in the diagrams corresponds to the adhesion preventive unit power source 12 illustrated in FIG. 1.

The sputtering apparatus according to the modification example 2 includes a switch 31 for switching a polar character of the voltage V applied between the adhesion preventive unit electrode 9 and the stage electrode 13 by the adhesion preventive unit power source 12. When the polar character of the voltage V is switched using the switch 31, the direction of the electrical field between the adhesion preventive unit electrode 9 and the stage electrode 13 can be switched. The adhesion preventive unit power source 12 may include the switch 31.

According to the modification example 2, when the direction of the electrical field between the adhesion preventive unit electrode 9 and the stage electrode 13 is a downward direction (a direction from the adhesion preventive unit electrode 9 toward the stage electrode 13), the spatter particles can be made to adhere to the end portion of the substrate 6 in the manner similar to the embodiment 1. When the direction of the electrical field between the adhesion preventive unit electrode 9 and the stage electrode 13 is an upward direction (a direction from the stage electrode 13 toward the adhesion preventive unit electrode 9), the sputter particles can be made to adhere to the adhesion preventive unit 7. Accordingly, adhesion of the sputter particles to the unnecessary area can be prevented.

### Embodiment 2

Described in the present embodiment 2 is a method of manufacturing a semiconductor device using the sputtering apparatus according to the embodiment 1.

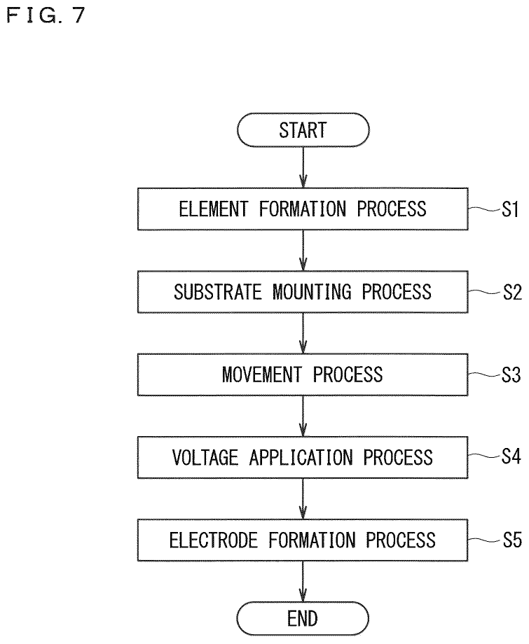

FIG. 7 is a flow chart illustrating a method of manufacturing a semiconductor device according to the embodiment 2. The following description focuses primarily on the manufacturing process using the sputtering apparatus according to the embodiment 1.

In an element formation process in Step S1, ions are implanted into the substrate 6 to form the element.

In a substrate mounting process in Step S2, the substrate 6 is mounted to the electrostatic chuck stage 5.

In a movement process in Step S3, the adhesion preventive unit 7 and the electrostatic chuck stage 5 are brought close to each other.

In a voltage application process in Step S4, voltage is applied between the adhesion preventive unit electrode 9 and the stage electrode 13 using the adhesion preventive unit power source 12.

In an electrode formation process in Step S5, electrical discharge is started and the electrode is formed on the substrate 6.

The element formation process in Step S1 is executed using the other apparatus instead of the sputtering apparatus according to the embodiment 1. That is to say, the element formation process in Step S1 is the process previously executed before the manufacturing process using the sputtering apparatus according to the embodiment 1.

After the electrode formation process in Step S5, the semiconductor device as a product is completed through the processes of dicing, wire bonding, and resin sealing of the substrate 6, for example.

According to the embodiment 2, in-plane uniformity of a film thickness distribution in the whole substrate 6 after the sputtering can be ensured by using the sputtering apparatus according to the embodiment 1. Thus, a large number of semiconductor devices can be manufactured from one substrate 6. Since the adhesion preventive unit 7 and the substrate 6 do not have contact with each other in the sputtering, damage on the substrate 6 can be prevented. Such a configuration contributes to improvement of a yield of the semiconductor device.

Each embodiment can be arbitrarily combined, or each embodiment can be appropriately varied or omitted within the scope of the present disclosure.

### APPENDIX

The aspects of the present disclosure are collectively described hereinafter as appendixes.

### (Appendix 1)

A sputtering apparatus, comprising:
a vacuum chamber;
a stage to which a substrate is mounted in the vacuum chamber; and
an adhesion preventive unit disposed to be separated from the substrate between a sputter target provided in the vacuum chamber and an end portion of the substrate, wherein
the adhesion preventive unit includes an adhesion preventive unit electrode disposed via an insulating part,
the stage includes a stage electrode disposed in an end portion, and
a power source is disposed between the adhesion preventive unit electrode and the stage electrode.

### (Appendix 2)

The sputtering apparatus according to Appendix 1, wherein
the power source applies voltage between the adhesion preventive unit electrode and the stage electrode, and
when the voltage is V, a distance from the adhesion preventive unit to the end portion of the stage is D, and a width of the adhesion preventive unit electrode is L, 0<VL²/D²≤60 is satisfied.

### (Appendix 3)

The sputtering apparatus according to Appendix 1, wherein
the adhesion preventive unit electrode is disposed on an outer side than the stage electrode.

### (Appendix 4)

The sputtering apparatus according to Appendix 1, further comprising
a switch switching a polar character of the voltage applied between the adhesion preventive unit electrode and the stage electrode by the power source.

### (Appendix 5)

A method of manufacturing a semiconductor device using the sputtering apparatus according to Appendix 1, comprising:
(a) mounting the substrate to the stage;
(b) bringing the adhesion preventive unit and the stage close to each other;
(c) applying voltage between the adhesion preventive unit electrode and the stage electrode; and
(d) starting electrical discharge and forming an electrode in the substrate, wherein
in the (c), when the voltage is V, a distance from the adhesion preventive unit to the end portion of the stage is D, and a width of the adhesion preventive unit electrode is L, 0<VL²/D²≤60 is satisfied.

### (Appendix 6)

The method of manufacturing the semiconductor device according to Appendix 5, further comprising
(e) implanting ions into the substrate and forming an element before the (a).

While the disclosure has been shown and described in detail, the foregoing description is in all aspects illustrative and not restrictive. It is therefore understood that numerous modifications and variations can be devised.

What is claimed is:

1. A sputtering apparatus, comprising:
a vacuum chamber;
a stage to which a substrate is mounted in the vacuum chamber; and
an adhesion preventive unit disposed to be separated from the substrate between a sputter target provided in the vacuum chamber and an end portion of the substrate, wherein
the adhesion preventive unit includes an adhesion preventive unit electrode disposed via an insulating part,
the stage includes a stage electrode disposed in an end portion, and
a power source is disposed between the adhesion preventive unit electrode and the stage electrode.

2. The sputtering apparatus according to claim 1, wherein
the power source applies voltage between the adhesion preventive unit electrode and the stage electrode, and
when the voltage is V, a distance from the adhesion preventive unit to the end portion of the stage is D, and a width of the adhesion preventive unit electrode is L, 0<VL²/D²≤60 is satisfied.

3. The sputtering apparatus according to claim 1, wherein
the adhesion preventive unit electrode is disposed on an outer side than the stage electrode.

4. The sputtering apparatus according to claim 1, further comprising
a switch switching a polar character of the voltage applied between the adhesion preventive unit electrode and the stage electrode by the power source.

5. A method of manufacturing a semiconductor device using the sputtering apparatus according to claim 1, comprising:
(a) mounting the substrate to the stage;
(b) bringing the adhesion preventive unit and the stage close to each other;
(c) applying voltage between the adhesion preventive unit electrode and the stage electrode; and
(d) starting electrical discharge and forming an electrode on the substrate, wherein
in the (c), when the voltage is V, a distance from the adhesion preventive unit to the end portion of the stage is D, and a width of the adhesion preventive unit electrode is L, 0<VL²/D²≤60 is satisfied.

6. The method of manufacturing the semiconductor device according to claim 5, further comprising
(e) implanting ions into the substrate and forming an element before the (a).
